(19) United States
(12) Patent Application Publication
(10) Pub. No.: US 2026/0156863 A1
(43) Pub. Date: Jun. 4, 2026

(54) CORNER-PROTECTED SQUARE-CELL SILICON CARBIDE PLANAR METAL-OXIDE-SEMICONDUCTOR FIELD-EFFECT TRANSISTOR

(71) Applicant: Renesas Electronics Corporation, Tokyo (JP)

(72) Inventors: Kijeong HAN, Morrisville, NC (US); Meng Chia LEE, Dallas, TX (US); Dilip Madhav RISBUD, San Jose, CA (US)

(73) Assignee: Renesas Electronics Corporation, Tokyo (JP)

(21) Appl. No.: 18/968,185

(22) Filed: Dec. 4, 2024

(51) Int. Cl. H10D 30/66; H10D 30/01; H10D 62/10; H10D 62/832

(52) U.S. Cl. CPC H10D 30/665; H10D 30/0291; H10D 62/109; H10D 62/127; H10D 62/8325

(57) ABSTRACT

A semiconductor structure includes a silicon carbide semiconductor substrate of a first conductivity type having an upper surface and a bottom surface. The semiconductor structure further includes a drift region of the first conductivity type located on the upper surface of the semiconductor substrate. The upper surface having a transistor region and peripheral regions located at each corner of the transistor region. The transistor region further includes a channel region of a second conductivity type, opposite to the first conductivity type, located above the drift region and positioned on a center portion of the transistor region, a source region of the first conductivity type adjacent to the channel region, and a gate electrode located above the drift region via a gate oxide, the gate electrode surrounds the source region. Each of the peripheral regions includes a first semiconductor region of the second conductivity type formed above the drift region.

### BACKGROUND

The present disclosure generally relates to the field of semiconductor devices, and more particularly to planar metal-oxide-semiconductor field-effect transistors (MOSFETs).

The rapid advancement of power electronics has created a growing demand for high-performance semiconductor devices capable of operating at elevated voltages, temperatures, and frequencies. MOSFETs are integral components in modern power conversion and management systems, utilized in applications ranging from electric vehicles and renewable energy systems to industrial motor drives.

Among the various semiconductor materials, silicon carbide (SiC) has gained significant attention due to its superior properties, such as a wide bandgap, high thermal conductivity, and excellent electric field breakdown strength. These characteristics make SiC an ideal candidate for high-voltage and high-temperature applications, outperforming traditional silicon-based devices in terms of efficiency and thermal performance.

However, the design and fabrication of SiC MOSFETs come with unique challenges. Traditional planar MOSFET structures often suffer from issues related to electric field concentration, particularly at the cell corners. This can lead to premature device breakdown, reduced reliability, and diminished overall performance, particularly under high-stress conditions. To address these limitations, innovative designs are necessary to improve the robustness and performance of SiC MOSFETs.

### SUMMARY

According to an embodiment of the present disclosure, a semiconductor structure includes a semiconductor substrate of a first conductivity type having an upper surface and a bottom surface. The semiconductor substrate including a silicon carbide substrate. The semiconductor structure further includes a drift region of the first conductivity type located on the upper surface of the semiconductor substrate. The upper surface having a transistor region and peripheral regions located at each corner of the transistor region. The transistor region further includes a channel region of a second conductivity type opposite to the first conductivity type located above the drift region, the channel region being positioned on a center portion of the transistor region, a source region of the first conductivity type adjacent to the channel region, and a gate electrode located above the drift region via a gate oxide, the gate electrode surrounding the source region. Each of the peripheral regions includes a first semiconductor region of the second conductivity type formed above the drift region.

According to another embodiment of the present disclosure, a semiconductor structure includes a semiconductor substrate of a first conductivity type having an upper surface and a bottom surface. The semiconductor substrate including a silicon carbide substrate. The semiconductor structure further includes a drift region of the first conductivity type located on the upper surface of the semiconductor substrate. The upper surface having a plurality of transistor regions and a plurality of peripheral regions. A first transistor region of the plurality of transistor regions is adjacent to a second transistor region of the plurality of transistor regions. The first transistor region including first peripheral regions of the plurality of peripheral regions located at each corner of the first transistor region. The second transistor region including second plurality of peripheral regions of the plurality of peripheral regions located at each corner of the first transistor region. The plurality of transistor regions includes a channel region of a second conductivity type opposite to the first conductivity type located above the drift region, the channel region being positioned on a center portion of the plurality of transistor regions, a source region of the first conductivity type adjacent to the channel region, and a gate electrode located above the drift region via a gate oxide, the gate electrode surrounding the source region. Each of the plurality of peripheral regions includes a first semiconductor region of the second conductivity type formed above the drift region.

According to yet another embodiment of the present disclosure, a semiconductor structure includes a semiconductor substrate of a first conductivity type, the semiconductor substrate includes silicon carbide. The semiconductor structure further includes a drift region of the first conductivity type located above the semiconductor substrate, a JFET region of the first conductivity type located above the drift region, a base region of a second conductivity type located above the JFET region, the second conductivity type being opposite to the first conductivity type, a shielding region of the second conductivity type located above the JFET region and adjacent to the base region, and a source region of the first conductivity type located above the base region. A portion of the base region is located between the source region and the shielding region.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a top-down view of a semiconductor structure illustrating a quadrilateral-cell configuration, according to an embodiment of the present disclosure;

FIG. 2 is a top-down view of the semiconductor structure depicting first unit cell and second unit cell, according to an embodiment of the present disclosure;

FIG. 3 is a cross-sectional view of the first unit cell taken along line AA′ as depicted in FIG. 2, according to an embodiment of the present disclosure;

FIG. 4 is a cross-sectional view of the second unit cell taken along line BB′ as depicted in FIG. 2, according to an embodiment of the present disclosure;

FIG. 5 is a top-down view of a semiconductor structure depicting a hexagonal-cell configuration, according to an embodiment of the present disclosure; and

FIG. 6 is a flowchart depicting operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

Conventional planar MOSFET designs frequently face problems with electric field concentration at the corners of the cells which can result in early device failure, decreased reliability, and lower overall performance. More particularly, in conventional square-cell topology for SiC MOSFETs, the capacitance between the gate and drain electrodes (Cgd or Crss) is often increased, adversely affecting switching speed and leading to higher switching energy loss and overall power consumption. Additionally, square-cell corners are susceptible to high electric fields, which can compromise gate oxide reliability and device performance. The design constraints associated with placing P+ contacts centrally limit their size, further contributing to these issues.

Corner-Protected Square-Cell (CPSC) design presents a promising solution to these challenges. By incorporating protective features at the corners of the square cell structure, this design mitigates electric field concentrations, enhancing device reliability and breakdown voltage. The square cell configuration further optimizes the packing density, allowing for greater scalability in power applications.

Accordingly, embodiments of the present disclosure provides a planar SiC MOSFET with a corner-protected square-cell design that addresses these challenges by incorporating P+ islands at the square corners. The proposed cell design can reduce Cgd through shielding effects, which enhances switching speed and lowers energy losses. By protecting the junction field-effect transistor (JFET) corners and interior regions, the P+ islands can improve gate oxide reliability, resulting in more robust device operations. Furthermore, embodiments of the present disclosure allow to separate P+ and N+ contacts for an increased P+ contact area which can minimize the risk of NPN latch-up during Unclamped Inductive Switching (UIS) and short circuit tests. Accordingly, the proposed embodiments can optimize switching performance and enhance reliability and efficiency of SiC planar MOSFETs in high-performance power electronics applications.

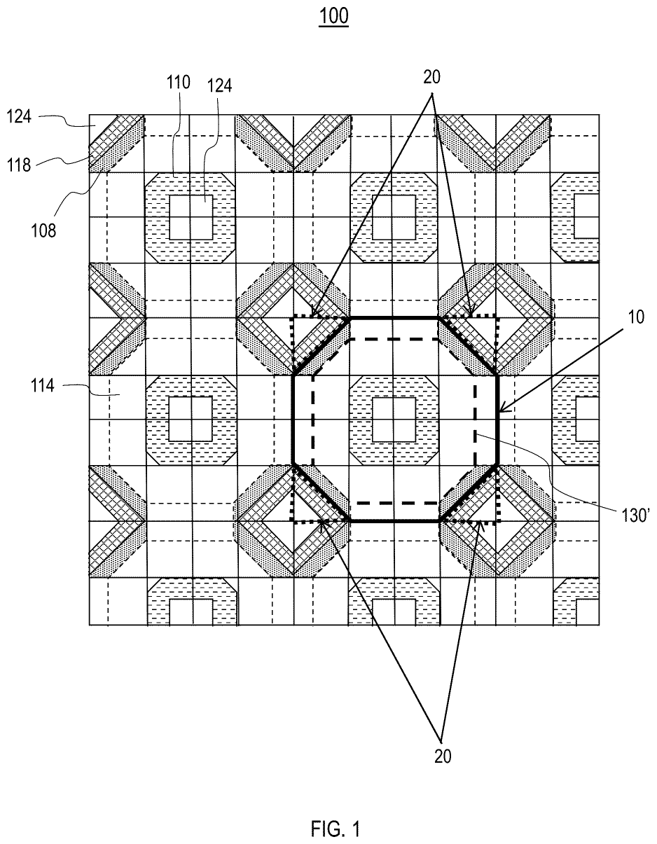

Embodiments by which the corner-protected square-cell planar SiC MOSFET can be formed is described in detail below by referring to the accompanying drawings in FIGS. 1-6.

FIG. 1 is a top-down view of a semiconductor structure 100 illustrating components of a corner-protected square-cell planar SiC MOSFET. In this embodiment, the semiconductor structure 100 includes at least one transistor region 10 and peripheral regions 20 located at each corner of each one of the at least one transistor region 10.

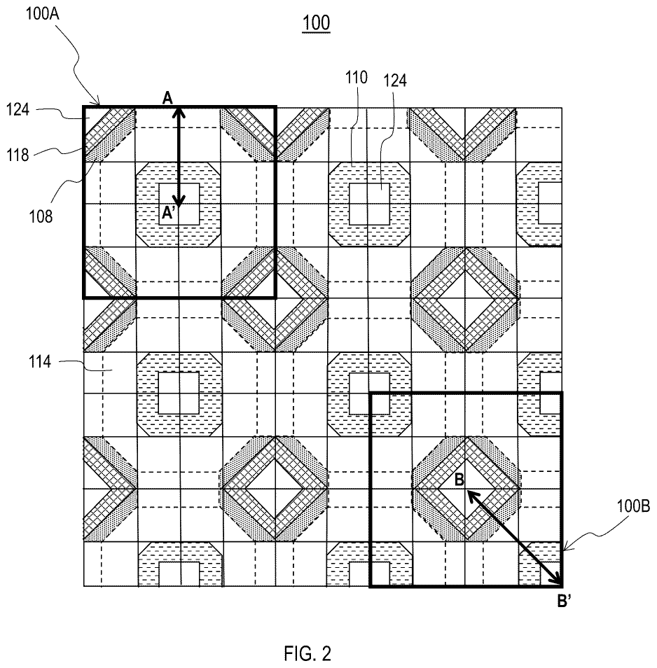

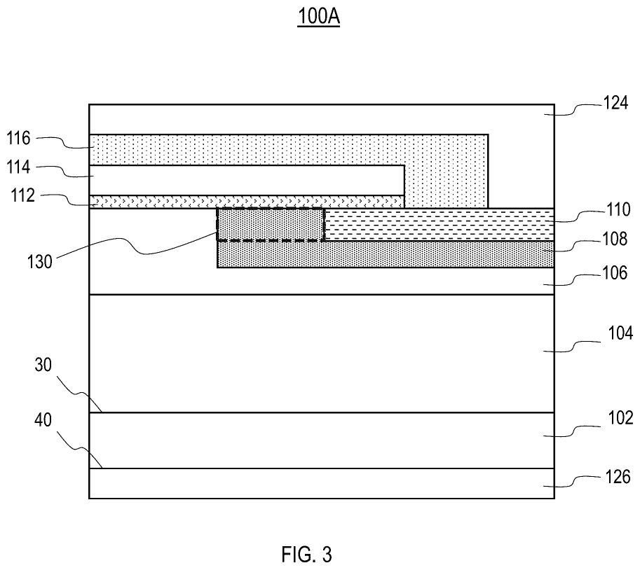

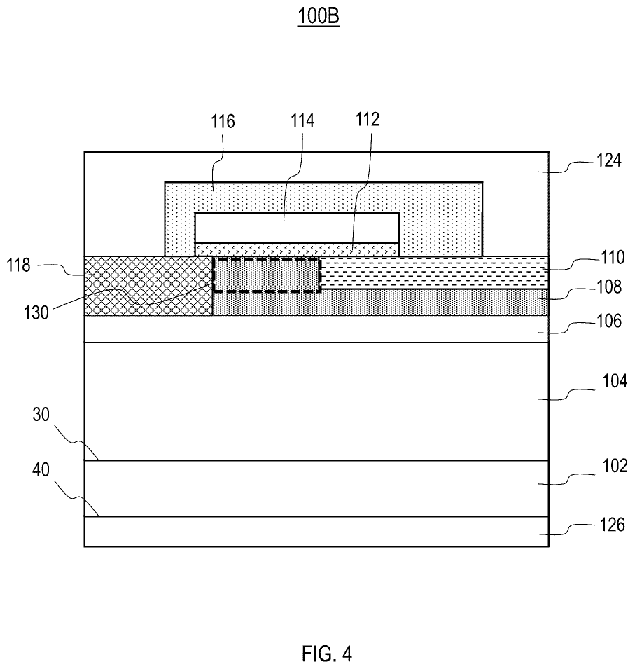

FIG. 2 depicts first unit cell 100A and second unit cell 100B of the semiconductor structure 100. FIG. 3 is a cross-sectional view of first unit cell 100A of semiconductor structure 100 taken along line AA′. FIG. 4 is a cross-sectional view of second unit cell 100B of semiconductor structure 100 taken along line BB′.

With reference now to FIGS. 1-4 simultaneously, according to an embodiment the semiconductor structure 100 includes a semiconductor substrate (hereinafter “substrate”) 102 of a first conductivity type made of silicon carbide (SiC). A thickness of the initial substrate 102 is approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 30 and a bottom surface 40, as depicted in FIGS. 3-4. According to an embodiment, transistor region 10 and peripheral regions 20, as depicted in FIG. 1, are formed on the upper surface 30 of the substrate 102. In one or more embodiments, a total area of the peripheral regions 20 is approximately 15% of a total area of the transistor region 10. The total area of peripheral regions 20 can be reduced to facilitate current flow while still effectively covering the cell corners.

A drift region 104 of the first conductivity type is formed on the upper surface 30 of the substrate 102. The drift region 104 is made of silicon carbide with an added impurity concentration that is lower than the impurity concentration of substrate 102. In general, drift region 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift region 104 can be formed by chemical vapor deposition (CVD) of the semiconductor material (i.e., SiC).

A thickness of the drift region 104 is determined by the device voltage rating. For example, the thickness of the drift region 104 can be approximately 10 μm for 1.2 kV rated devices. The impurity concentration of the drift region 104 can be approximately 1×10¹⁶ cm⁻³ for 1.2 kV rated devices. However, the impurity concentration of the drift region 104 is not limited to this value and may be in a range of approximately 1×10¹⁴ cm⁻³ to approximately 1×10¹⁷ cm⁻³ depending on the device voltage rating.

According to an embodiment, each transistor region 10 of the semiconductor structure 100 includes a junction field effect transistor (JFET) region 106, a base region 108 formed above the JFET region 106, a source region 110 formed above the base region 110, a gate oxide 112 formed above and in contact with JFET region 106, base region 108 and source region 110, a gate electrode 114 formed above the gate oxide 112, an interlevel dielectric layer 116 formed above the gate electrode, and a top metal layer 124 formed above the interlevel dielectric layer 116. Similarly, each peripheral region 20 includes a shielding region 118 in at least partial contact with top metal layer 124. Although not depicted in the figures, it can be understood that semiconductor structure 100 includes multiple first unit cells 100A that are adjacent to each other. Each first unit cell 100A contains a transistor region 10, with peripheral regions 20 located at each corner of the transistor regions 10. For clarity, transistor region 10 and peripheral regions 20 are illustrated separately from first and second unit cells 100A, 100B in the figures. In an embodiment, transistor region 10 includes a quadrilateral shape (e.g., square or rectangular) and peripheral regions 20 include a triangular shape.

With continued reference to FIGS. 1-4, the JFET region 106 is formed above and in contact with the drift region 104. In some instances, JFET region 106 can be formed with a higher donor doping of the first conductivity type that can vary between approximately 1×10¹⁵ cm⁻³ and approximately 1×10¹⁸ cm⁻³. A thickness of the JFET region 106 is approximately 0.1 μm to approximately 3.5 μm.

The base region 108 includes a doped semiconductor region of a second conductivity type formed above the JFET region 106. A thickness of the base region 108 is approximately 0.1 μm to approximately 1.0 μm. The impurity concentration of the base region 108 can vary between approximately 1×10¹⁹ cm⁻³ to approximately 1×10²¹ cm⁻³. The second conductivity type can be P-type or N-type. Generally, the second conductivity type is opposite to the first conductivity type. In an embodiment, a channel region 130 of the second conductivity type is formed within base region 108. Channel region 130 is disposed above and in contact with JFET region 106 (FIGS. 3-4) and adjacent to source region 110 (FIGS. 3-4) and shielding region 118 (FIG. 4). Channel region 130 can be positioned on a center portion of the transistor region 10 as depicted by projection line 130′ in FIG. 1.

The source region 110 is formed above and in contact with the base region 108. A thickness of the source region 110 is approximately 0.1 μm to approximately 0.5 μm. Source region 110 may include a heavily-doped semiconductor layer of the first conductivity type. A dopant concentration of source region 110 can vary, for example, between 1×10¹⁹ cm⁻³ and 1×10²¹ cm⁻³.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor layers.

With continued reference to FIGS. 1-4, shielding region 118 is formed above and in contact with JFET region 106 and adjacent to base region 108, as depicted in the cross-sectional view of FIG. 4. The location of shielding region 118 can also be appreciated in the top-down views of semiconductor structure 100 shown in FIGS. 1-2. Shielding region 118 includes a semiconductor region composed of a heavily doped silicon carbide layer of the second conductivity type. An ion implantation process can be conducted on the semiconductor structure 100 to form shielding region 118. Shielding region 118 can be formed with an impurity concentration of the second conductivity type varying between approximately 1×10¹⁹ cm⁻³ and approximately 1×10²¹ cm⁻³. In embodiments in which the second conductivity type is P-type, shielding region 118 can be referred to as P+ region. A thickness of shielding region 118 can vary between approximately 0.1 μm and approximately 3.5 μm.

As illustrated in FIGS. 1 and 2, shielding region 118 can be formed on each peripheral region 20 of semiconductor structure 100, with each shielding region 118 being in contact with a corner of the transistor region 10. This configuration creates a corner-protected square-cell (CPSC) design, incorporating protective features (e.g., shielding regions 118) at the corners to mitigate electric field concentrations in these areas of the semiconductor structure 100.

The shielding regions 118 are arranged in an island-like manner at each corner of the transistor region 10, meaning they are structured as isolated clusters or segments that resemble “islands.” These island-like shielding regions 118 at the square corners help reduce the gate-drain capacitance (Cgd) through shielding effects, enhancing switching speed and reducing energy losses. In an embodiment, a shape of shielding regions 118 is a quadrilateral shape.

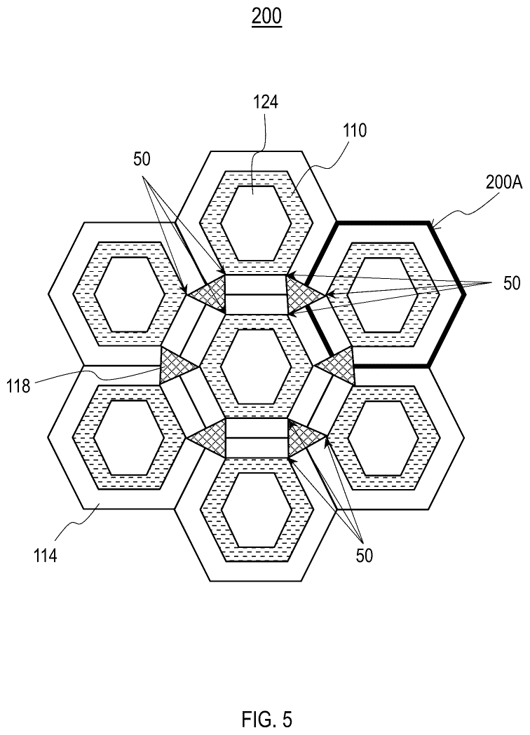

Furthermore, the island-like shielding regions 118 can protect the corners of the JFET region 106 (as shown in FIG. 5), which improves gate oxide reliability and leads to more robust device operation. The proposed placement of shielding regions 118 allows for the separation of P+ and N+ contacts which can increase the P+ contact area and minimize the risk of NPN latch-up during UIS and short-circuit tests.

With continued reference to FIGS. 1-4, the gate oxide 112 can be formed above shielding region 118, base region 108 and source region 110 using various types of deposition processes. The gate oxide 112 can electrically separate a subsequently formed gate electrode from active areas of the semiconductor structure 100. In one or more embodiments, gate oxide 112 can be formed by conformal deposition of a gate insulating film. Non-limiting examples of gate insulating films to form gate oxide 112 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the gate oxide 112 can vary between approximately 10 nm to approximately 100 nm.

The process of forming gate electrode 114 usually includes depositing a conductive material, such as polysilicon, above the gate electrode 112. The gate electrode 114 and gate oxide 112 provide a gate structure for the semiconductor structure 100. After forming the gate electrode 114, interlevel dielectric layer 116 can be formed to fill voids and electrically isolate active regions within the semiconductor structure 100. The interlevel dielectric layer 116 is disposed above the gate electrode 114. More particularly, the interlevel dielectric layer 116, as depicted in FIGS. 3 and 4, covers an upper surface and opposite sidewalls of gate electrode 114, opposite sidewalls of gate oxide 112, and partially covers an upper surface of shielding region 118 and source region 110. In one or more embodiments, the interlevel dielectric layer 116 can be formed by, for example, conformal deposition (e.g., CVD) of a dielectric material such as silicon oxide, silicon nitride, and the like. In one or more embodiments, a patterning process can be conducted on the interlevel dielectric layer 116 to achieved the shape shown in the figures.

In an embodiment, a top metal layer 124 is deposited above the interlevel dielectric layer 116 and above exposed portions of source region 110 and shielding region 118, as shown in FIG. 4. The top metal layer 124 provides a source terminal or source electrode that electrically contacts source region 110 and shielding region 118.

A bottom metal layer 126 can be formed on the bottom surface 40 of the substrate 102. The bottom metal layer 126 serves as a drain terminal or drain electrode that provides electrical (ohmic) contact with substrate 102.

FIG. 5 is a top-down view of a semiconductor structure 200 depicting a distribution of shielding regions 118 within a hexagonal SiC power MOSFET. The difference between cell unit 200A of the hexagonal SiC power MOSFET and first unit cell 100A of the square-cell power MOSFET shown in FIGS. 1 to 4 is that the gate electrode 114 has a hexagonal layout. Thus, in this embodiment, shielding region 118 connects multiple mutually separated gate electrodes 114. The shape and position of each shielding region 118 is defined by adjacent vertices 50 of multiple source regions 110 connecting to it. (e.g., defined by the shortest straight line between adjacent vertices 50). Accordingly, in this embodiment, shielding regions 118 formed on a periphery of each cell unit 200A are of substantially triangular shape. Stated differently, a shape of the shielding regions 118 is a triangle formed by the connection of three vertices 50 of three adjacent source regions 110. Although not depicted in the figure, it can be understood that shielding regions 118 are formed on each cell unit 200A of the semiconductor structure 100 connecting vertices 50 of adjacent source regions 110.

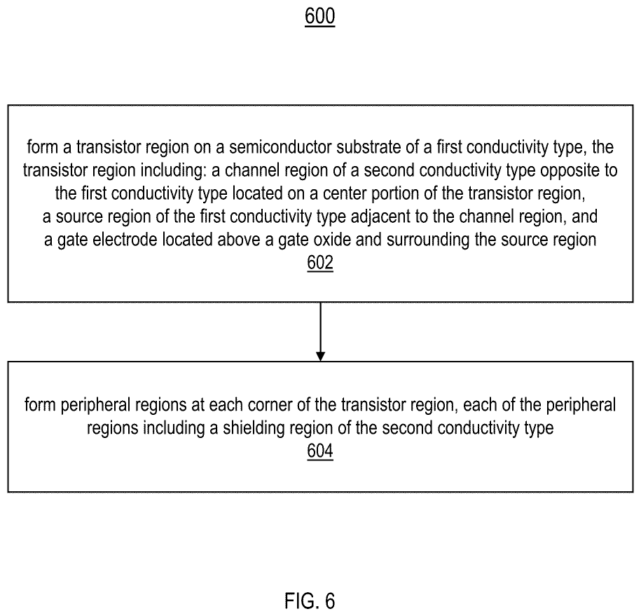

Referring now to FIG. 6, a flowchart 600 depicting operational steps for the fabrication of the semiconductor structure 100 is shown, according to an embodiment of the present disclosure.

The process starts at step 602 by forming a transistor region on a semiconductor substrate of a first conductivity type. According to an embodiment, formation of the transistor region includes forming a channel region of a second conductivity type opposite to the first conductivity type. The channel region is located on a center portion of the transistor region. Formation of the transistor region further includes forming a source region of the first conductivity type adjacent to the channel region, and forming a gate electrode above a gate oxide. In an embodiment, the gate electrode surrounds the source region. According to an embodiment, the transistor region includes a quadrilateral shape. In other embodiments, the transistor region includes a hexagonal shape.

The process continues at step 604 by forming peripheral regions at each corner of the transistor region. Each of the peripheral regions includes a shielding region of the second conductivity type. According to an embodiment, each of the peripheral regions has a triangular shape and the shielding region is positioned in an island-like manner at each corner of the transistor region. The shielding region includes a heavily doped semiconductor region of the second conductivity type with an impurity concentration of the shielding region (P+ region) being more than 1×10¹⁹ cm⁻³ and approximately 1×10²¹ cm⁻³. In one or more embodiments, a total area of the peripheral regions is approximately 15% of a total area of the transistor region.

The process of forming the transistor region and peripheral regions further includes forming a drift region above the semiconductor substrate, forming a JFET region above the drift region, forming an interlevel dielectric layer above the gate electrode, forming a top metal layer above the interlevel dielectric layer, with the top metal layer being electrically connected to the source region and shielding region, and forming a bottom metal layer located on a bottom surface of the semiconductor substrate.

### EXAMPLES

### Example 1

A method of forming a semiconductor structure comprising:
forming a transistor region on a semiconductor substrate of a first conductivity type, the transistor region including:
   a channel region of a second conductivity type opposite to the first conductivity type, the channel region being located on a center portion of the transistor region;
   a source region of the first conductivity type adjacent to the channel region; and
   a gate electrode located above a gate oxide, the gate electrode surrounding the source region;
forming peripheral regions at each corner of the transistor region, each of the peripheral regions including a shielding region of the second conductivity type.

### Example 2

The method according to Example 1, wherein the transistor region includes a quadrilateral shape.

### Example 3

The method according to Example 1, wherein the transistor region includes a hexagonal shape.

### Example 4

The method according to Example 1, wherein each of the peripheral regions has a triangular shape.

### Example 5

The method according to Example 1, wherein the shielding region is positioned in an island-like manner at each corner of the transistor region.

### Example 6

The method according to Example 1, wherein the shielding region includes a heavily doped semiconductor region of the second conductivity type.

### Example 7

The method according to Example 1, wherein an impurity concentration of the shielding region varies from 1×10¹⁹ cm⁻³ to 1×10²¹ cm⁻³.

### Example 8

The method according to Example 1, wherein a total area of the peripheral regions is approximately 15% of a total area of the transistor region.

### Example 9

The method according to Example 1, wherein a location of each shielding region increases a P+ contact area.

### Example 10

The method according to Example 1, further comprising:
forming a drift region above the semiconductor substrate;
forming a JFET region above the drift region;
forming an interlevel dielectric layer above the gate electrode;
forming a top metal layer above the interlevel dielectric layer, the top metal layer being electrically connected to the source region and shielding region; and
a bottom metal layer located on a bottom surface of the semiconductor substrate.

### Example 11

A method of forming a semiconductor structure, comprising:
forming a semiconductor substrate of a first conductivity type, the semiconductor substrate having an upper surface and a bottom surface, the semiconductor substrate including a silicon carbide substrate;
forming a drift region of the first conductivity type above the upper surface of the semiconductor substrate; and
forming a transistor region and peripheral regions on the upper surface of the semiconductor substrate, wherein at least one peripheral region is formed at each corner of the transistor region, the transistor region including:
   a channel region of a second conductivity type opposite to the first conductivity type of the drift layer, the channel region being positioned on a center portion of the transistor region;
   a source region of the first conductivity type adjacent to the channel region; and
   a gate electrode located above the drift layer via a gate oxide, the gate electrode surrounding the source region;
   wherein each of the peripheral regions includes a first semiconductor region of the second conductivity type.

### Example 12

The method according to Example 11, wherein the first semiconductor region is located adjacent and electrically connected to the channel region.

### Example 13

The method according to Example 11, wherein an impurity concentration of the first semiconductor region is higher than an impurity concentration of the channel region.

### Example 14

The method according to Example 13, wherein the impurity concentration of the first semiconductor region is from 1×10¹⁹ cm⁻³ to 1×10²¹cm⁻³.

### Example 15

The method according to Example 11, wherein the transistor region has a quadrilateral shape.

### Example 16

The method according to Example 11, wherein the transistor region has a hexagonal shape.

### Example 17

The method according to Example 11, wherein each of the peripheral regions has a triangular shape.

### Example 18

The method according to Example 11, wherein a total area of the peripheral regions is approximately 15% of a total area of the transistor region.

### Example 19

The method according to Example 11, wherein the first semiconductor region includes a P+ region and a location of the first semiconductor region increases a P+ contact area.

### Example 20

The method according to Example 11, further comprising:
forming a JFET region above the drift region;
forming a top metal layer above and electrically connected to the source region and first semiconductor region; and
forming a bottom metal layer on the bottom surface of the semiconductor substrate.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a semiconductor substrate of a first conductivity type having an upper surface and a bottom surface, the semiconductor substrate including a silicon carbide substrate; and
a drift region of the first conductivity type located on the upper surface of the semiconductor substrate,
wherein:
the upper surface has a transistor region and peripheral regions located at each corner of the transistor region, the transistor region including:
a channel region of a second conductivity type opposite to the first conductivity type located above the drift region, the channel region being positioned on a center portion of the transistor region;
a source region of the first conductivity type adjacent to the channel region; and
a gate electrode located above the drift region via a gate oxide, the gate electrode surrounding the source region; and
each of the peripheral regions includes a first semiconductor region of the second conductivity type formed above the drift region.

2. The semiconductor structure according to claim 1, wherein the first semiconductor region is located adjacent and electrically connected to the channel region.

3. The semiconductor structure according to claim 1, wherein an impurity concentration of the first semiconductor region is higher than an impurity concentration of the channel region.

4. The semiconductor structure according to claim 1, wherein an impurity concentration of the first semiconductor region is from 1×10¹⁹ cm⁻³ to 1×10²¹ cm⁻³.

5. The semiconductor structure according to claim 1, wherein the transistor region has a rectangular shape.

6. The semiconductor structure according to claim 1, wherein the transistor region has a square shape.

7. The semiconductor structure according to claim 1, wherein each of the peripheral regions has a triangular shape.

8. The semiconductor structure according to claim 1, wherein a total area of the peripheral regions is approximately 15% of a total area of the transistor region.

9. The semiconductor structure according to claim 8, wherein the first semiconductor region is in contact with each corner of the transistor region.

10. The semiconductor structure according to claim 1, further comprising:
a JFET region located above the drift region;
a top metal layer above and electrically connected to the source region and first semiconductor region; and
a bottom metal layer located on the bottom surface of the semiconductor substrate.

11. A semiconductor structure comprising:
a semiconductor substrate of a first conductivity type having an upper surface and a bottom surface, the semiconductor substrate including a silicon carbide substrate; and
a drift region of the first conductivity type located on the upper surface of the semiconductor substrate,
wherein:
the upper surface has a plurality of transistor regions and a plurality of peripheral regions, a first transistor region of the plurality of transistor regions being adjacent to a second transistor region of the plurality of transistor regions, the first transistor region including first peripheral regions of the plurality of peripheral regions located at each corner of the first transistor region, the second transistor region including second plurality of peripheral regions of the plurality of peripheral regions located at each corner of the first transistor region, the plurality of transistor regions including:
a channel region of a second conductivity type opposite to the first conductivity type located above the drift region, the channel region being positioned on a center portion of the plurality of transistor regions;
a source region of the first conductivity type adjacent to the channel region; and
a gate electrode located above the drift region via a gate oxide, the gate electrode surrounding the source region; and
each of the plurality of peripheral regions includes a first semiconductor region of the second conductivity type formed above the drift region.

12. The semiconductor structure according to claim 11, wherein the first semiconductor region is located adjacent and electrically connected to the channel region.

13. The semiconductor structure according to claim 11, wherein an impurity concentration of the first semiconductor region is higher than an impurity concentration of the channel region.

14. The semiconductor structure according to claim 11, wherein the plurality of transistor regions has a quadrilateral shape.

15. The semiconductor structure according to claim 11, wherein each of the plurality of peripheral regions has a triangular shape.

16. The semiconductor structure according to claim 11, wherein a total area of the first peripheral regions is approximately 15% of a total area of the first transistor region.

17. The semiconductor structure according to claim 16, wherein the first semiconductor region is in contact with each corner of the plurality of transistor regions.

18. The semiconductor structure according to claim 11, further comprising:
a JFET region located above the drift region;
a top metal layer above and electrically connected to the source region and first semiconductor region; and
a bottom metal layer located on the bottom surface of the semiconductor substrate.

19. A semiconductor structure comprising:
a semiconductor substrate of a first conductivity type, the semiconductor substrate including silicon carbide;
a drift region of the first conductivity type located above the semiconductor substrate;
a JFET region of the first conductivity type located above the drift region;
a base region of a second conductivity type located above the JFET region, the second conductivity type being opposite to the first conductivity type;
a shielding region of the second conductivity type located above the JFET region and adjacent to the base region; and
a source region of the first conductivity type located above the base region, a portion of the base region being located between the source region and the shielding region.

20. The semiconductor structure according to claim 19,
wherein the semiconductor substrate includes a transistor region with the shielding region positioned in an island-like manner at each corner of the transistor region, and
wherein the transistor region further comprises:
a gate oxide disposed, at least partially, above the JFET region, base region, source region and shielding region;
a gate electrode disposed above the gate oxide;
an interlevel dielectric layer disposed above the gate electrode and, at least partially, above the source region and shielding region;
a top metal layer disposed above the interlevel dielectric layer and electrically connected to the source region and shielding region; and
a bottom metal layer disposed on a bottom surface of the semiconductor substrate.
